(19) United States
(12) Patent Application Publication
(10) Pub. No.: US 2014/0375472 A1
(43) Pub. Date: Dec. 25, 2014

(54) METHOD AND SYSTEM FOR MEASUREMENT OF RESOURCE METERS

(71) Applicant: Enbala Power Networks Inc., North Vancouver (CA)

(72) Inventor: John Todd Sankey, Vancouver (CA)

(73) Assignee: ENBALA POWER NETWORKS INC., North Vancouver (CA)

(21) Appl. No.: 14/370,647

(22) PCT Filed: Jan. 10, 2013
(86) PCT No.: PCT/CA2013/000016

§ 371 Date: Jul. 3, 2014

Related U.S. Application Data
(60) Provisional application No. 61/585,134, filed on Jan. 10, 2012.

(51) Int. Cl. G01D 4/00; G01R 22/00

(52) U.S. Cl. CPC G01D 4/002; G01R 22/00
USPC 340/870.02

(57) ABSTRACT

The present disclosure is directed at methods, systems, and techniques for measurements and, optionally, auditing of resource meters such as electricity meters. Each of multiple site aggregation units receive measurements from resource meters. Each of the site aggregation units generate a site aggregation digest that substantially uniquely identifies the resource measurements, stores these digests, and aggregates the resource measurements into site aggregation data that is sent to a central aggregation unit. The central aggregation unit generates a central aggregation digest that substantially uniquely identifies the site aggregation data, stores this digest, and aggregates the site aggregation data into central aggregation data that is sent to a resource provider with the central aggregation digest. When auditing is to be performed, the site and central aggregation digests can be used to verify the authenticity of the resource measurements and the site aggregation data, respectively.

### TECHNICAL FIELD

This disclosure relates generally to a method and system for measurement of resource meters, such as electricity meters.

### BACKGROUND

Resources, such as gas, water, and electricity, are ubiquitously used in society. Electricity, for example, is a currency, providing a convenient means of transporting energy from a source such as falling water, the sun or wind to end users. Electricity is delivered at the speed of light and it is used the instant that it is created.

Utilities that generate and deliver electricity use a number of services. Their primary service is energy capacity, which is the delivery of energy to end users via electricity. They also use supporting services, called ancillary services, to achieve and maintain balance between supply and demand in the power system. These ancillary services include, but are not limited to, providing system regulation, operating reserves, and demand response. Utilities measure the degree to which they rely on these ancillary services with electricity meters.

### SUMMARY

According to a first aspect, there is provided a method for measurement of resource meters, the method comprising receiving, from each of multiple site aggregation units (i) site aggregation data comprising aggregated resource measurements from at least one of the resource meters, wherein the site aggregation data from all the site aggregation units comprise aggregated resource measurements from all of the resource meters; and (ii) a site aggregation digest that substantially uniquely identifies the resource measurements; storing the site aggregation digests received from the multiple site aggregation units; aggregating the site aggregation data received from the site aggregation units into central aggregation data; and transmitting the central aggregation data to a resource distributor.

The site aggregation digest may be generated by applying a site cryptographic hash function to the site aggregation data.

Aggregating the site aggregation data received from the site aggregation units into the central aggregation data may comprise summing the site aggregation data received from the site aggregation units.

The method may further comprise generating a central aggregation digest that substantially uniquely identifies the site aggregation data received from the multiple site aggregation units; and transmitting the central aggregation digest to the resource distributor.

The central aggregation digest may be generated by applying a central cryptographic hash function to the site aggregation data received from the site aggregation units.

The central cryptographic hash function may be applied to the site aggregation data and the site aggregation digests.

Each of the site aggregation units may aggregate the resource measurements into the site aggregation data by summing the resource measurements.

The site aggregation data may be stored in a database located remotely from a processor that aggregates the site aggregation data. Similarly, the central aggregation data may be stored remotely from a processor that aggregates the central aggregation data.

The resource may be electric energy and the resource distributor may be an electric utility or an independent system operator.

The resource distributor may store the central aggregation digest and the method may further comprise the resource distributor auditing the site aggregation data by regenerating the central aggregation digest from the site aggregation data that has been stored; comparing the central aggregation digest that is regenerated to the central aggregation digest stored by the resource distributor; and determining that the site aggregation data is authentic when the central aggregation digest that is regenerated is identical to the central aggregation digest stored by the resource distributor.

Each of the site aggregation units may store the resource measurements used to generate the site aggregation data and digests, and the method may further comprise auditing the resource measurements transmitted by any one of the site aggregation units by, at the site aggregation unit being audited (“audited site aggregation unit”), regenerating the site aggregation digest from the resource measurements stored by the audited site aggregation unit; comparing the site aggregation digest that is regenerated to the site aggregation digest received from the audited site aggregation unit and that has been stored by the central aggregation unit; and determining that the resource measurements are authentic when the site aggregation digest that is regenerated is identical to the site aggregation digest received from the audited site aggregation unit and that has been stored.

The method may further comprise auditing the resource meters that send the resource measurements to any one of the site aggregation units (“audited resource meter”) by reading a present value measurement from the audited resource meter; comparing the present value measurement to the resource measurement received and stored by the site aggregation unit to which the audited resource meter is sending the present value measurement; and verifying the consistency of the resource measurement that is stored with the present value measurement.

According to another aspect, there is provided a system for measurement of resource meters, the system comprising a processor; and a computer readable medium communicatively coupled to the processor and having encoded thereon statements and instructions to perform any of the foregoing methods.

According to another aspect, there is provided a non-transitory computer readable medium having encoded thereon statements and instructions to cause a processor to perform a method any of the foregoing methods.

This summary does not necessarily describe the entire scope of all aspects. Other aspects, features and advantages will be apparent to those of ordinary skill in the art upon review of the following description of specific embodiments.

### BRIEF DESCRIPTION OF THE FIGURES

In the accompanying drawings, which illustrate one or more exemplary embodiments:

FIG. 1 shows a system for measurement and auditing of electricity meters, according to one embodiment.

FIG. 2 shows a method for measurement of resource meters, according to another embodiment.

Figure shows an embodiment of a method for generating and transmitting a central aggregation digest to a resource provider.

FIG. 4 show an embodiment of a method for auditing resource meters.

### DETAILED DESCRIPTION

Utilities that generate and delivery electricity using the primary service of energy capacity also typically use ancillary services such as providing system regulation, operating reserves, and demand response. A description of these three particular types of ancillary services follows:
1. System Regulation (a.k.a. Balancing): This service adjusts load or generation based on commands from an Automatic Generation Control (AGC) system at the System Control Centre of a utility to provide second by second balance between the power that is generated and the power that is consumed. The AGC system sends control signals every few seconds to continuously maintain this balance. System regulation has traditionally been provided by generators, but loads and storage devices are now also being used to provide this service.
2. Operating Reserves: There are several types of reserves that fit into this category, and all are used to provide extra power at times when the power system is experiencing shortages or an unexpected loss of generation.
3. Demand Response: At peak load times, utilities may offer customers a payment to reduce their consumption for a period of time.

As electricity is, in effect, a form of energy currency, it is precisely measured using electricity meters so that there can be proper accounting for all services, including ancillary services, exchanged. Historically each electricity meter is a completely standalone, self-contained unit measuring and recording electrical delivery/usage and demand (energy and power) for a controlled collection of devices or financial entity such as a generator owner or building owner. These meters were designed primarily for the purpose of regular billing, usually monthly, and generally required manual data collection. Fraud prevention was achieved through a physical seal on the device to prevent tampering, and data collection was by visual inspection of a spinning dial or similar display element. Recent innovations in this space generally still contemplate independent, sealed meters but enhanced with remote reading capability and are often called “Smart Meters”. Because of the physical seal and the self-contained nature of these devices, they are quite expensive, on the order of thousands of dollars per unit.

Some of the embodiments described herein achieve the fraud prevention goals of helping to ensure data integrity, but allow the use of much less expensive data storage and remote communication technology than found in Smart Meters. They do this by not requiring the measurement devices to act as both a data storage device and a data communication device. The measurement device still has the same physical integrity of the historical devices, and even the Smart Meters, but the method and system described here can leverage low-cost, widespread, commodity storage and communication technologies, without giving up the tamper resistance. Further, because the commodity technologies have improved by several orders of magnitude recently, the method and system can be used for services, such as ancillary services, requiring much higher performance than has historically been possible with typical electrical meters with their very limited storage and communication capabilities.

Network Overview

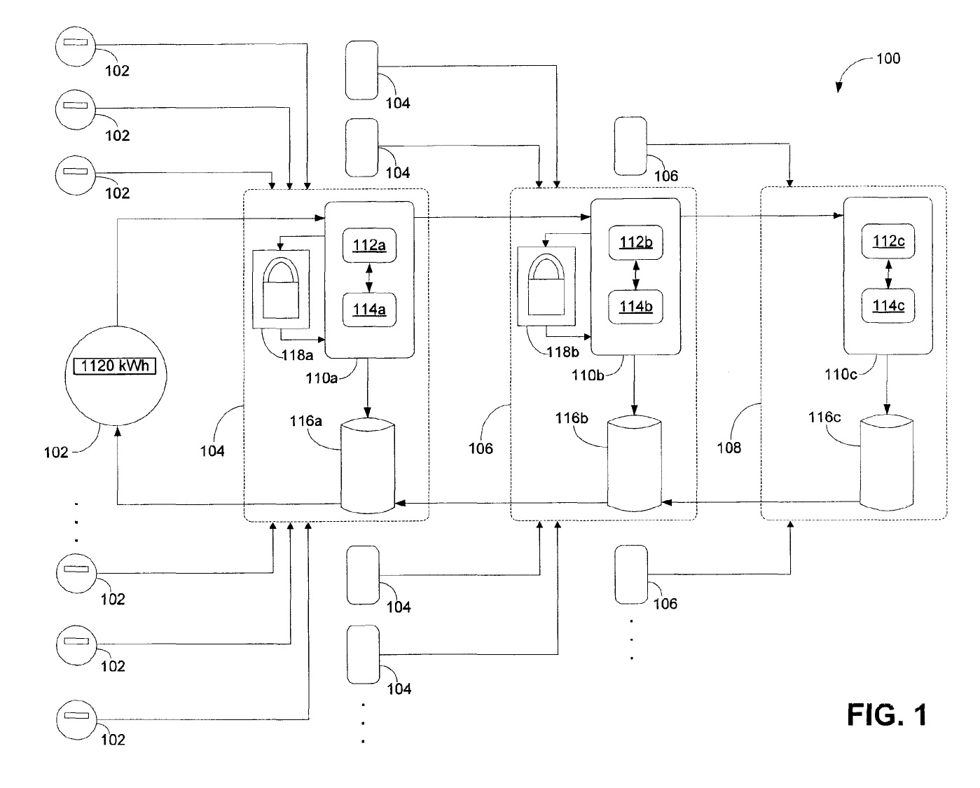

Referring now to FIG. 1, there is shown one embodiment of a system 100 for the measurement and auditing of electricity meters. A plurality of electricity meters 102, monitoring electrical energy usage, are situated throughout an electrical power system and electrically coupled to a plurality of electrical resources (not shown) within the electrical power system. Each of the electricity meters 102 is in communication with a designated local site aggregation unit 104. Typically, the local site aggregation unit 104 will be in communication with a plurality of the electricity meters 102 located at a host site for one of the electrical resources. This communication is performed over common and inexpensive communication channels, such as RS-485 or Ethernet. The local site aggregation units 104 collect, aggregate, and retain telemetry data from the meters 102 for control and audit purposes, using databases 116a comprising common and inexpensive storage technology such as magnetic or solid state media. Such storage technology can be used to store many months worth of very high resolution measurement from multiple meters 102, such as one set of readings per second per meter 102 for one year.

Each of the local site aggregation units 104 is in communication with one or more central aggregation units 106, again over common, low-cost channels such as cable or ADSL modems connected to the Internet. The central aggregation units 106 collect, aggregate, and retain telemetry data from the local site aggregation units 104 for control and audit purposes. The central aggregation units 106 are in communication with a power system operator such as an Independent System Operator (ISO) or utility.

The electricity meters 102 may comprise any device capable of measuring instantaneous electrical operating parameters of a resource that does any one or more of generate, consume, and store electricity. By “consume” electricity, it is meant to use electricity to perform work. The electrical resources may comprise electrical generators having capacity to generate electricity (“generation resources”), electrically-powered devices having capacity to consume electricity (“load resources”), and storage devices having capacity to store energy and later release it back to the electrical power system (“storage resources”).

The site aggregation units 104 and central aggregation units 106 may each comprise one or more servers or controllers in communication with each other through one or more networks or communication mediums. Each of the electricity meters 102 sends electricity measurements to the one or more site aggregation units 104 with which it is in communication. Similarly, and as discussed in more detail below, each of the site aggregation units 104 communicates data to the one or more central aggregation units 106 to which it is connected and each of the central aggregation units 106 stores electricity measurements in the associated database 116b, and transmits data to the power system operator 108, which may be an ISO or utility.

Each of the servers and controllers generally comprises one or more processors and one or more computer readable media in communication with each other through one or more networks or communication mediums. The one or more processors may comprise any suitable processing device known in the art, such as, for example, application specific circuits, programmable logic controllers, field programmable gate arrays, microcontrollers, microprocessors, virtual machines, and electronic circuits. The one or more computer readable media may comprise any suitable memory devices known in the art, such as, for example, random access memory, flash memory, read only memory, hard disc drives, optical drives, optical drive media, and flash drives.

For example, in the embodiment of FIG. 1, the site aggregation units 104 each comprise a server 110a in communication with a database 116a that resides on a long term storage medium. The server 110a comprises a processor 112a and a computer readable medium 114a in communication with each other. The central aggregation units 106 similarly each comprise a server 110b in communication with a database 116b that resides on a long term storage medium. The server 110b comprises a processor 112b and a computer readable medium 114b in communication with each other. The power system operator 108 receives data from the central aggregation units 106 via a server 110c that also comprises a processor 112c and a computer readable medium 114c in communication with each other, and stores this data in a database 116c. Collectively, the servers 110a-c are collectively hereinafter the “servers 110”, the processors 112a-c are collectively hereinafter the “processors 112”, the databases 116a-c are collectively hereinafter the “databases 116”, and the media 114a-c are collectively hereinafter the “media 114”. While the databases 116 and the processors 112 for each of the site aggregation unit 104, central aggregation unit 106, and distributor 108 are shown as being collocated in FIG. 1, in alternative embodiments storage and processing functions may not be collocated.

Operation

The general operating principles of the system 100 are as follows:
(a) Resource host sites to the central aggregation unit 106: The local site aggregation units 104 located at the resource host sites aggregate all instantaneous electrical measurements from the electricity meters 102 of applicable loads, generation, and storage resources at the resource host sites. This signals are reported back to the central aggregation unit 106.
(b) The central aggregation unit 106 to the ISO or utility: The central aggregation unit 106 reports aggregated measurements to the ISO or utility. These measurements are the aggregate measurements of all resources currently providing a particular service to the ISO or utility.

Data Collection and Storage

In the system 100, the installed electricity meters 102 sense and calculate the instantaneous electrical operation for each resource providing service. Each of the meters 102 communicates using an industrial communications protocol, such as Modbus RTU, a measurement data stream comprising these resource measurements directly with one of the site aggregation units 104 of the power system. The site aggregation unit 104 collects, timestamps, aggregates into what is hereinafter referred to as “site aggregation data”, and stores in the database 116a instantaneous readings from the locally installed electrical meters 102 for resources providing service. As the instantaneous readings are received and aggregated into the site aggregation data by the site aggregation unit 104, a secure site cryptographic hash algorithm 118a, such as MD-5, SHA-1, SHA-256, or SHA-3, is run on each measurement data stream to produce a digest value for each measurement type (e.g. energy, real power, reactive power, etc.). The individual and aggregated readings and digest values are continually logged in a long term format at the database 116a of the local site aggregation unit 104 for a desired minimum period (e.g. two years).

At a predetermined rate (e.g. every two seconds or the maximum permitted rate where network or hardware limitations exist) each of the site aggregation units 104 transmits the site aggregation data and the computed digest values to the central aggregation unit 106. As shown in FIG. 1, the central aggregation unit 106 receives site aggregation data from multiple site aggregation units 104. As the central aggregation unit 106 collects data from the site aggregation units 104, the data are again aggregated and a secure central cryptographic hash algorithm 118b is run on the centrally aggregated data stream to produce central aggregation digests. All site aggregation data, central aggregation data, site aggregation digests and central aggregation digests are stored in a long term data format at the database 116b of the central aggregation unit 106 for a desired minimum period (e.g. two years).

At a rate determined by the ISO or utility, the central aggregation data and digest are transmitted by the central aggregation unit 106 to the power system operator 108. The power system operator 108 stores the central aggregation data and digest and, in the present embodiment, does not store or even receive the site aggregation data or digests.

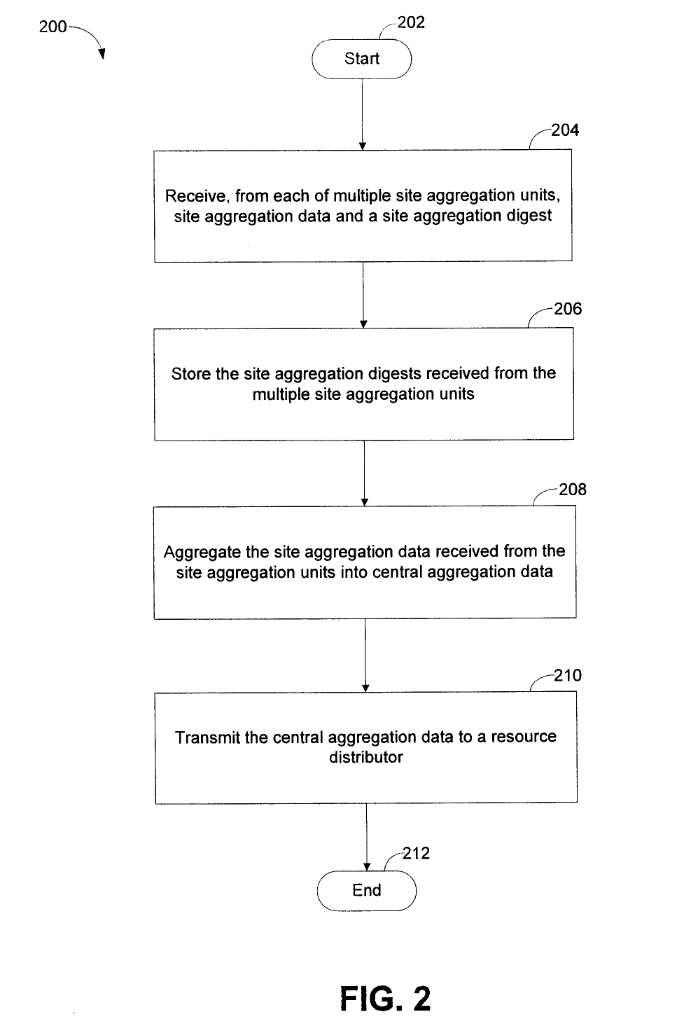

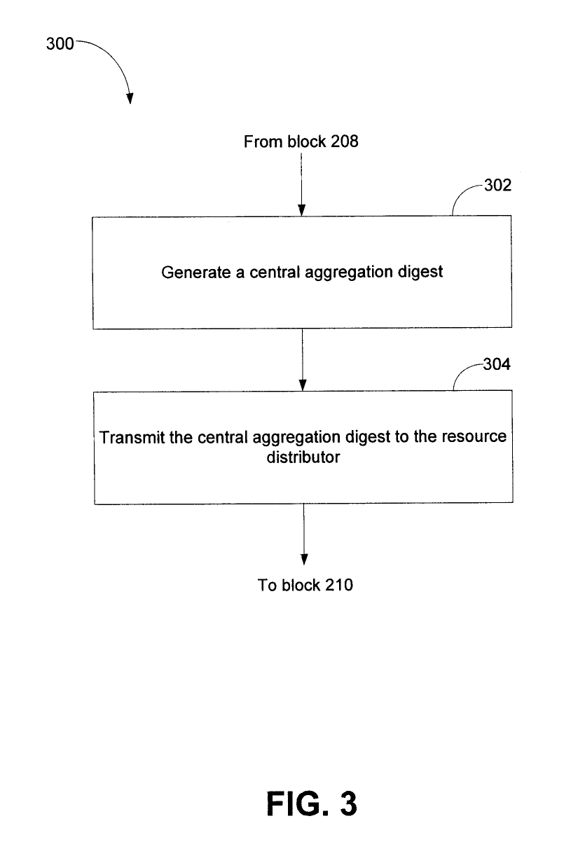

An example of the foregoing is depicted in the exemplary methods 200,300 of FIGS. 2 and 3, respectively. In FIG. 2, the processor 112b in the central aggregation unit 106 begins at block 202 and proceeds to block 204 where it receives, from each of the multiple site aggregation units 104, the site aggregation data comprising aggregated resource measurements from the resource meters 102, such as electricity measurements of electric energy measured using electricity meters. For any group of meters 102 being measured, the site aggregation data that the central aggregation unit 106 receives from all of the site aggregation units 104 comprise aggregated resource measurements from all of the meters 102. The processor 112b also receives a site aggregation digest from each of the site aggregation units 104, with the site aggregation digest substantially uniquely identifying the resource measurements received by that site aggregation unit 104 that are aggregated to form the site aggregation data for that site aggregation unit 104. By “substantially uniquely identifying”, it is meant that a person can rely on the fact that the site aggregation digest will change in an unpredictable manner when the underlying resource measurements used to generate the site aggregation digest changes. The processor 112b then stores in the database 116b the site aggregation digests received from the site aggregation units 104; optionally, the processor 112b may also store all the site aggregation data in the database 116b as well.

At block 206, the processor 112b aggregates the site aggregation data received from the site aggregation units 104 into the central aggregation data. When the resource measurements comprise electric energy readings, the processor 112b sums the site aggregation data together to generate the central aggregation data. The processor 112b then proceeds to block 210 where it transmits the central aggregation data to a resource distributor 108, such as a power system operator, which may be a utility or ISO. The method 200 then ends at block 212.

As discussed in further detail below, during an auditing procedure, the site aggregation digests are used to verify the authenticity of the resource measurements that are aggregated to generate the site aggregation data. To facilitate verifying the authenticity of the site aggregation data, the processor 112b may generate the central aggregation digest, which substantially uniquely identifies the site aggregation data. The processor 112b can accordingly proceed to block 302 from block 208 where it generates this digest by applying the central cryptographic hash function to the site aggregation data received from the site aggregation units. At block 304, the processor 112b sends the central aggregation digest to the resource distributor 108.

Once the resource distributor 108 has the central aggregation data and the central aggregation digest and wants to verify the authenticity of the measurements used to generate this data, the distributor 108 may audit any one or more of the central aggregation unit 106, the site aggregation unit 106, and the resource meters 102.

Auditing

At any point where an aggregation of data is performed, one of the secure hash algorithms 118a,b produces a corresponding digest value. The central aggregation data and digest values are made available to the power system operator 108 continuously over a communications link using a communication protocol (e.g. DNP3). The operator 108 can continuously read and log the aggregated data values and digests in a long term format to be used for auditing.

When later auditing a service provider, either the central or site aggregation units 106,104, the archived aggregated data values and digests can be collected from the database 116b at the central aggregation unit or the database 116a at the site aggregation unit for that service provider. To validate the authenticity of the archived data, the operator 108 executes the secure hash algorithm 116a,b with the archived data to produce corresponding digests and checks that stored digests match the recomputed digests. If the digest values generated by the secure hash algorithm run by the operator 108 match the digest values that were collected and logged from the central and site aggregation units, the data has not been tampered with and is considered to be accurate.

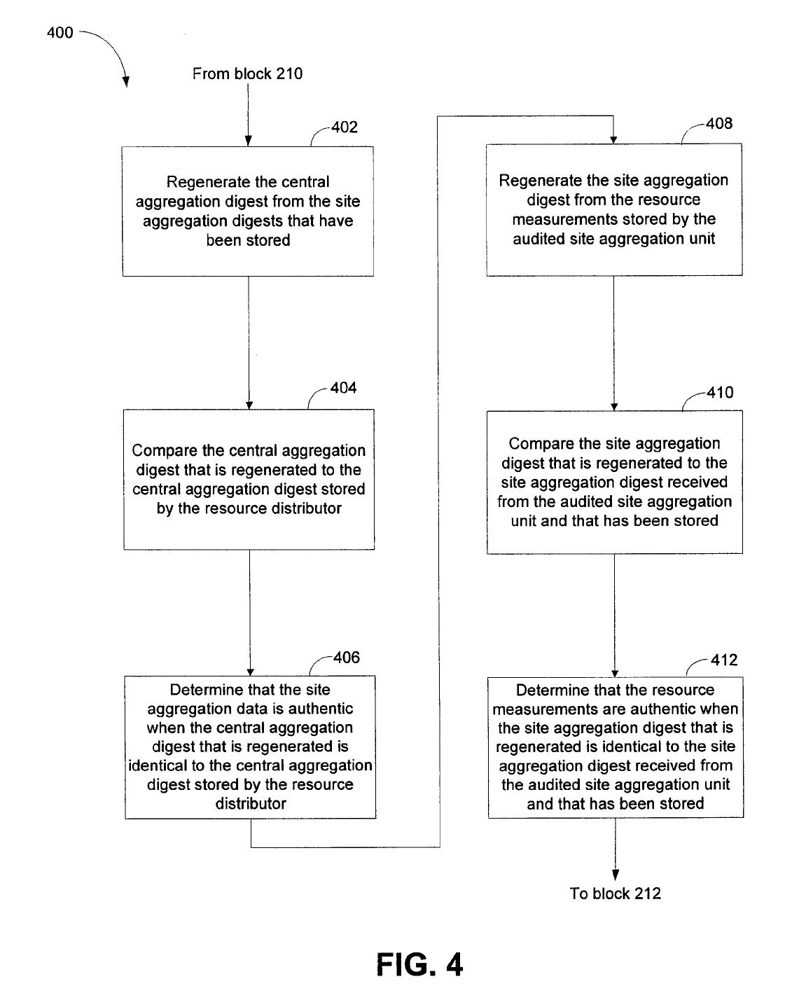

An example of the foregoing auditing process is shown in the exemplary method 400 shown in FIG. 4, which may be performed after block 210. At block 402, the distributor 108 regenerates the central aggregation digest from the site aggregation data that are stored in the database 116b at the central aggregation unit 106. At block 404, the distributor 108 then compares the regenerated central aggregation digest to the central aggregation digest that the distributor 108 received and stored and that substantially uniquely identifies the central aggregation data whose authenticity is being audited. When the central aggregation digest that is regenerated is identical to the central aggregation digest stored by the distributor 108, the distributor 108 concludes that the site aggregation data used to generate the central aggregation data has not been tampered with after being received and stored by the central aggregation unit 106 (block 408).

The central aggregation unit 106 may also audit any one or more of the site aggregation units 104 to determine whether the resource measurements received by the site aggregation units 104 have been tampered with. At block 408, for any one of the site aggregation units (“audited site aggregation unit”), the processor 112b regenerates the site aggregation digest from the resource measurements stored by the audited site aggregation unit in its database 116a. At block 410, the processor 112b compares the regenerated site aggregation digest to the site aggregation digest that the central aggregation unit 106 received and stored and that substantially uniquely identifies the site aggregation data whose authenticity is being audited. When the site aggregation digest that is regenerated is identical to the site aggregation digest stored in the database 116b at the central aggregation unit 106, the processor 112b concludes that the resource measurements used to generate the site aggregation data have not been tampered with after being received and stored by the site aggregation unit 106 (block 410).

Following auditing of the site aggregation units 104, to ensure that the resource meters 102 have not been tampered with the meters 102 themselves may be audited. For any one of the resource meters 102 being audited (“audited resource meter”), a present value measurement from the audited resource meter 102 is obtained by reading the meter 102. The present value measurement is then compared to the resource measurement previously received and stored by the site aggregation unit 104 to which the audited resource meter 102 is sending the present value measurement. The consistency of the stored resource measurements can be verified using the present value measurement and the stored resource measurements. For example, when the stored resource measurements are of power and the present value measurement is of energy, energy can be integrated over time since the resource measurements were obtained to generate a power reading. This power reading can be compared to the stored resource measurements, which represent historical power readings, to verify consistency of the stored resource measurements.

Resource Measurement Method

Each site aggregation unit 104 totals the instantaneous electrical measurements from the meters 102 measuring resources currently providing service and telemeters the aggregated measurements to the central aggregation unit 106. The central aggregation unit 106 totals all site aggregation units 104 and passes these measurements to the system operator 108.

Asset Measurement Technique

Accurate telemetry data may be provided by employing one of the following measurement methods:
(a) Resource Only Measurement: The instantaneous power is measured for the resources providing regulation only. This specific case may only be applied to resources that are considered to be independent.
(b) Facility Wide Measurement: The instantaneous power is measured for the resource host facility which may do one or both of:
   (i) exclude specific loads or generation that are independent to the resource providing regulation; and
   (ii) add or subtract metered values to determine the aggregate regulation being provided.

Regardless of the measurement technique used, the instantaneous power readings for the EDC meter (or a meter in parallel with the EDC meter) can be logged and stored in a long-term format as per market rules requirements.

In one embodiment a resource will be considered independent where a change in the instantaneous power of the regulating resource has an ‘insignificant correlation’ to the instantaneous power value from the EDC meter when the resource meter 102 is subtracted out. In the present embodiment, an ‘insignificant correlation’ occurs where a resource has a correlation coefficient between −0.25 to 0.25 over any five minute time period.

The correlation coefficient (r) may be defined by the equation:

$$r = \frac{ n Σ x y - Σ x Σ y}{\sqrt{[ n Σ {x}^{2} - {( Σ x )}^{2} ] [ n Σ {y}^{2} - {( Σ y )}^{2} ]}}$$

where:
n=number of sample point taken during a five minute period;
x=the instantaneous power of the resource meter; and
y=the instantaneous power of the resource meter subtracted from the instantaneous power of the EDC meter.

Aggregated Resource Set

The set of resources aggregated to provide regulation are selected prior to the regulation operating time frame. Once selected, the set of resources that form the aggregated response may not change until the end of the regulation operating time frame.

While in the foregoing embodiments electricity is the resource being measured and audited, in alternative embodiments difference resources may be measured. For example, water may be monitored by measuring the volume of water used and water pressure. Similarly, gas may be monitored by measured the volume of gas used as gas pressure.

Even when electricity is being monitored as in the foregoing examples, energy need not be monitored. In alternative embodiments, power (real or reactive), voltage, and current can alternatively or additionally be measured and audited.

In another alternative embodiments, digests can be generated by hashing not only data but previously generated digests. For example, instead of generating the central aggregation digest by hashing only the site aggregation data, both the site aggregation data and the site aggregation digests may be hashed to generate the central aggregation digest.

It is contemplated that any part of any aspect or embodiment discussed in this specification can be implemented or combined with any part of any other aspect or embodiment discussed in this specification.

For the sake of convenience, the exemplary embodiments above are described as various interconnected functional blocks. This is not necessary, however, and there may be cases where these functional blocks are equivalently aggregated into a single logic device, program or operation with unclear boundaries. In any event, the functional blocks can be implemented by themselves, or in combination with other pieces of hardware or software.

While particular embodiments have been described in the foregoing, it is to be understood that other embodiments are possible and are intended to be included herein. It will be clear to any person skilled in the art that modifications of and adjustments to the foregoing embodiments, not shown, are possible.

1. A method for measurement of resource meters, the method comprising:
(a) receiving, from each of multiple site aggregation units:
(i) site aggregation data comprising aggregated resource measurements from at least one of the resource meters, wherein the site aggregation data from all the site aggregation units comprise aggregated resource measurements from all of the resource meters; and
(ii) a site aggregation digest that substantially uniquely identifies the resource measurements;
(b) storing the site aggregation digests received from the multiple site aggregation units;
(c) aggregating the site aggregation data received from the site aggregation units into central aggregation data; and
(d) transmitting the central aggregation data to a resource distributor.

2. The method of claim 1 wherein the site aggregation digest is generated by applying a site cryptographic hash function to the site aggregation data.

3. The method of claim 1 wherein aggregating the site aggregation data received from the site aggregation units into the central aggregation data comprises summing the site aggregation data received from the site aggregation units.

4. The method of claim 1 further comprising:
(a) generating a central aggregation digest that substantially uniquely identifies the site aggregation data received from the multiple site aggregation units; and
(b) transmitting the central aggregation digest to the resource distributor.

5. The method of claim 4 wherein the central aggregation digest is generated by applying a central cryptographic hash function to the site aggregation data received from the site aggregation units.

6. The method of claim 5 wherein the central cryptographic hash function is applied to the site aggregation data and the site aggregation digests.

7. The method of claim 1 wherein each of the site aggregation units aggregates the resource measurements into the site aggregation data by summing the resource measurements.

8. The method of claim 1 where the site aggregation data is stored in a database located remotely from a processor that aggregates the site aggregation data.

9. The method of claim 1 wherein the resource is electric energy and the resource distributor is an electric utility or an independent system operator.

10. The method of claim 4 wherein the resource distributor stores the central aggregation digest and further comprising the resource distributor auditing the site aggregation data by:
(a) regenerating the central aggregation digest from the site aggregation data that has been stored;
(b) comparing the central aggregation digest that is regenerated to the central aggregation digest stored by the resource distributor; and
(c) determining that the site aggregation data is authentic when the central aggregation digest that is regenerated is identical to the central aggregation digest stored by the resource distributor.

11. The method of claim 11 wherein each of the site aggregation units stores the resource measurements used to generate the site aggregation data and digests, and further comprising auditing the resource measurements transmitted by any one of the site aggregation units by, at the site aggregation unit being audited (“audited site aggregation unit”):
(a) regenerating the site aggregation digest from the resource measurements stored by the audited site aggregation unit;
(b) comparing the site aggregation digest that is regenerated to the site aggregation digest received from the audited site aggregation unit and that has been stored by the central aggregation unit; and
(c) determining that the resource measurements are authentic when the site aggregation digest that is regenerated is identical to the site aggregation digest received from the audited site aggregation unit and that has been stored.

12. The method of claim 12 further comprising auditing the resource meters that send the resource measurements to any one of the site aggregation units (“audited resource meter”) by:
(a) reading a present value measurement from the audited resource meter;
(b) comparing the present value measurement to the resource measurement received and stored by the site aggregation unit to which the audited resource meter is sending the present value measurement; and
(c) verifying the consistency of the resource measurement that is stored with the present value measurement.

13. A system for measurement of resource meters, the system comprising:
(a) a processor; and
(b) a computer readable medium communicatively coupled to the processor and having encoded thereon statements and instructions to cause the processor to perform a method as claimed in claim 1.

14. A non-transitory computer readable medium having encoded thereon statements and instructions to cause a processor to perform a method as claimed in claim 1.
